(19) United States
(12) Patent Application Publication
(10) Pub. No.: US 2026/0190560 A1
(43) Pub. Date: Jul. 2, 2026

(54) ASSEMBLY SUBSTRATE

(71) Applicant: LG Display Co., Ltd., Seoul (KR)

(72) Inventors: Kiyong YANG, Seoul (KR); KyuOh KWON, Paju-si (KR); SeungJun LEE, Paju-si (KR); Myungsoo HAN, Goyang-si (KR)

(73) Assignee: LG Display Co., Ltd., Seoul (KR)

(21) Appl. No.: 19/383,359

(22) Filed: Nov. 7, 2025

(30) Foreign Application Priority Data
Dec. 31, 2024 (KR) 10-2024-0202029

(51) Int. Cl. H10H 29/03; H01L 21/683; H10H 29/01

(52) U.S. Cl. CPC H10H 29/03; H10P 72/74; H10H 29/012; H10P 72/7408; H10P 72/7434

(57) ABSTRACT

Provided is an assembly substrate for assembling a plurality of light emitting diodes. The assembly substrate includes an assembly base substrate, a plurality of first assembly electrodes disposed on the assembly base substrate, and a plurality of second assembly electrodes facing the plurality of first assembly electrodes with a selected interval. An insulating layer is disposed on the assembly base substrate and includes a plurality of openings overlapping the first and second assembly electrodes. A plurality of coils is disposed on the first and second assembly electrodes and encloses the openings. When a current is applied to the coils, magnetic fields are formed in the openings to attract and assemble light emitting diodes including magnetic material. The assembly substrate allows self assembly of light emitting diodes without the use of an external magnet, thereby simplifying the manufacturing process and improving assembly efficiency for display device fabrication.

### CROSS-REFERENCE TO RELATED APPLICATIONS

This application claims the priority of Korean Patent Application No. 10-2024-0202029 filed on Dec. 31, 2024, in the Korean Intellectual Property Office, the disclosure of which is incorporated herein by reference.

### BACKGROUND

### Technical Field

The present disclosure relates to an assembly substrate capable of easily assembling a light emitting diode LED.

### Description of the Related Art

Display devices used in computer monitors, TVs, and mobile phones include organic light emitting display (OLED) devices that emit light by themselves, and liquid crystal display (LCD) devices that require a separate light source.

The application range of display devices is expanding from computer monitors and TVs to personal portable devices, and research is being conducted on display devices having a large display area while having reduced volume and weight.

In addition, recently, display devices including light emitting diodes (LEDs) have attracted attention as next-generation display devices. Since LEDs are made of inorganic materials rather than organic materials, they have excellent reliability and longer lifespans compared to liquid crystal display devices and organic light emitting display devices. Moreover, LEDs not only have a fast lighting speed but also exhibit excellent light emission efficiency, strong impact resistance for high stability, and the capability to display high-brightness images.

### BRIEF SUMMARY

The present disclosure relates to an assembly substrate for light emitting diodes (LEDs) that integrates a plurality of micro coils around LED assembly openings to generate localized magnetic fields by applying direct current. These magnetic fields attract LEDs that contain a ferromagnetic material, allowing self assembly without the use of external magnets. In combination with electric fields formed by first and second assembly electrodes, the LEDs are attracted and precisely aligned within the openings through a magnetic and electric field assisted self assembly process.

Each coil may include multiple concentric or stacked coil electrodes positioned on one or more insulating layers. This arrangement concentrates the magnetic field in the opening region, improving field strength and uniformity while enabling selective activation of specific assembly areas. The inclusion of first and second wiring lines allows controlled current flow through each coil, providing simple electrical connectivity and localized field control across a large substrate.

By integrating the coils directly into the substrate, the configuration eliminates the need for separate magnetic components, simplifies manufacturing, and enhances scalability for large area display devices. It enables efficient and accurate LED assembly through precise electromagnetic control, supporting high yield production and process optimization in the fabrication of display panels.

Various embodiments of the present disclosure provide an assembly substrate capable of assembling a light emitting diode without a separate magnet.

Various embodiments of the present disclosure provide an assembly substrate capable of easily assembling a plurality of light emitting diodes, thereby improving production efficiency.

Technical benefits of the present disclosure are not limited to the above-mentioned benefits, and other benefits, which are not mentioned above, can be clearly understood by those skilled in the art from the following descriptions.

According to an aspect of the present disclosure, there is provided an assembly substrate for assembling a plurality of light emitting diodes. The assembly substrate includes an assembly base substrate, a plurality of first assembly electrodes disposed on the assembly base substrate, a plurality of second assembly electrodes facing the plurality of first assembly electrodes with a predetermined interval on the assembly base substrate, an insulating layer disposed on the assembly base substrate and including a plurality of openings that overlaps the plurality of first assembly electrodes and the plurality of second assembly electrodes, and a plurality of coils disposed on the plurality of first assembly electrodes and the plurality of second assembly electrodes and enclosing the plurality of openings.

Other detailed matters of the exemplary embodiments are included in the detailed description and the drawings.

According to the present disclosure, it is possible to assemble a light emitting diode by using a magnetic field formed by a direct current.

According to the present disclosure, it is possible to implement process optimization by assembling a plurality of light emitting diodes on a large-area assembly substrate.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of an assembly substrate according to an exemplary embodiment of the present disclosure;

FIG. 2 is an enlarged plan view of an assembly area of an assembly substrate according to an exemplary embodiment of the present disclosure;

FIG. 3 is a cross-sectional view taken along A-A′ of FIG. 2;

FIGS. 4A to 4D are process diagrams for illustrating a method of manufacturing a display device using an assembly substrate according to an exemplary embodiment of the present disclosure;

FIG. 5 is an enlarged plan view of an assembly area of an assembly substrate according to another exemplary embodiment of the present disclosure;

FIG. 6 is an enlarged plan view of an assembly area of an assembly substrate according to still another exemplary embodiment of the present disclosure;

FIG. 7 is a cross-sectional view taken along B-B′ of FIG. 6;

FIG. 8 is a cross-sectional view taken along C-C′ of FIG. 6; and

FIGS. 9A to 10D are process diagrams for illustrating a method of manufacturing an assembly substrate according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, the element or layer may be disposed directly on the other element or layer, or yet another element or layer may be interposed therebetween.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

The features of various embodiments of the present disclosure can be partially or entirely adhered to or combined with each other and can be interlocked and operated in technically various ways, and the embodiments can be carried out independently of or in association with each other.

Hereinafter, an assembly substrate according to exemplary embodiments of the present disclosure will be described in detail with reference to accompanying drawings

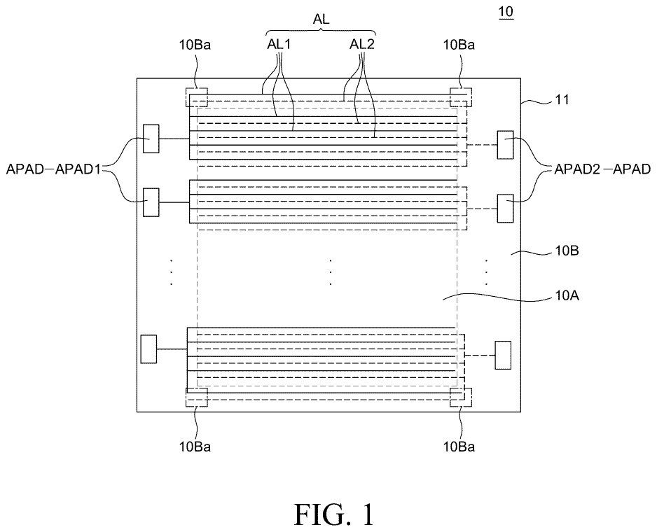

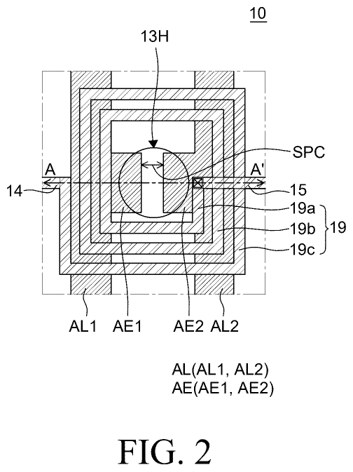

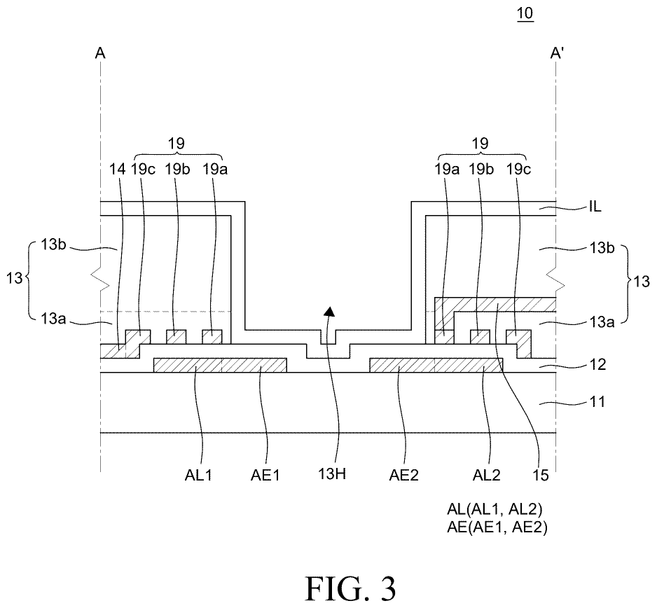

FIG. 1 is a plan view of an assembly substrate according to an exemplary embodiment of the present disclosure. FIG. 2 is an enlarged plan view of an assembly area of the assembly substrate according to an exemplary embodiment of the present disclosure. FIG. 3 is a cross-sectional view taken along A-A′ of FIG. 2.

Referring to FIGS. 1 and 2 together, an assembly substrate 10 includes an assembly area 10A and an outer area 10B. The assembly area 10A is an area in which a plurality of light emitting diodes is self-assembled, and a plurality of assembly lines AL and a plurality of assembly electrodes AE for self-assembling the light emitting diodes are disposed. The outer area 10B is the remaining area except for the assembly area 10A, and a plurality of assembly pads and a plurality of alignment keys may be disposed therein.

Referring to FIGS. 1 to 3, the assembly substrate 10 includes an assembly base substrate 11, a plurality of assembly lines AL, a plurality of assembly electrodes AE, a plurality of assembly pads, a passivation layer 12, an insulating layer 13, a first wiring line 14, a second wiring line 15, a plurality of coils 19, and a protective layer IL.

First, referring to FIG. 1, the outer area 10B includes at least one first alignment area 10Ba. For example, each of the plurality of first alignment areas 10Ba may be formed adjacent to each of four corners of the assembly area 10A.

In the first alignment area 10Ba, assembly lines AL and assembly electrodes AE may be further disposed on the assembly substrate 10.

Referring to FIGS. 2 and 3, in the assembly area 10A, the plurality of assembly lines AL, the plurality of assembly electrodes AE, the first wiring line 14, the second wiring line 15, and the plurality of coils 19 are disposed on the assembly base substrate 11.

The plurality of assembly lines AL includes a plurality of first assembly lines AL1 and a plurality of second assembly lines AL2. The plurality of first assembly lines AL1 and the plurality of second assembly lines AL2 may be disposed spaced apart from each other at a predetermined interval. The plurality of first assembly lines AL1 and the plurality of second assembly lines AL2 may be alternately disposed. Different voltages are applied to the plurality of first assembly lines AL1 and the plurality of second assembly lines AL2 so that an electric field may be formed between the plurality of first assembly lines AL1 and the plurality of second assembly lines AL2. A plurality of light emitting diodes may be self-assembled between the plurality of first assembly lines AL1 and the plurality of second assembly lines AL2 using the electric field formed therebetween.

Referring to FIG. 1, each of the plurality of first assembly lines AL1 extends from the assembly area 10A to the outer area 10B and may be electrically connected to the plurality of assembly pads in the outer area 10B.

Each of the plurality of second assembly lines AL2 extends from the assembly area 10A to the outer area 10B and may be electrically connected to the plurality of assembly pads in the outer area 10B.

Referring to FIGS. 2 and 3, the plurality of assembly electrodes AE includes a plurality of first assembly electrodes AE1 and a plurality of second assembly electrodes AE2. The plurality of first assembly electrodes AE1 may be connected to the plurality of first assembly lines AL1, and the plurality of second assembly electrodes AE2 may be connected to the plurality of second assembly lines AL2. A pair of the first assembly electrode AE1 and the second assembly electrode AE2 is disposed adjacent to each other to form an electric field for self-assembling the light emitting diode. Each pair of the first assembly electrode AE1 and the second assembly electrode AE2 may be disposed corresponding to an alignment position where the light emitting diode is transferred in a plurality of sub pixels.

The second assembly electrode AE2 connected to the second assembly line AL2 may face the first assembly electrode AE1 connected to the adjacent first assembly line AL1.

A plurality of light emitting diodes may be self-assembled between the first assembly electrode AE1 and the second assembly electrode AE2 facing each other at an interval and a disposition corresponding to each of the plurality of sub pixels.

Referring also to FIG. 1, the plurality of assembly pads is disposed on the assembly substrate 10 in the outer area 10B. The plurality of assembly pads includes a plurality of first assembly pads APAD1 and a plurality of second assembly pads APAD2. The plurality of first assembly lines AL1 and the plurality of first assembly electrodes AE1 are connected to the plurality of first assembly pads APAD1 so that a voltage may be applied, and the plurality of second assembly lines AL2 and the plurality of second assembly electrodes AE2 are connected to the plurality of second assembly pads APAD2 so that a voltage may be applied. Some of the plurality of first assembly lines AL1 may be connected to one first assembly pad APAD1, and some of the plurality of second assembly lines AL2 may be connected to one second assembly pad APAD2.

Referring to FIG. 3, a passivation layer 12 is disposed on the plurality of assembly lines AL and the plurality of assembly electrodes AE. The passivation layer 12 may protect the plurality of assembly lines AL and the plurality of assembly electrodes AE from a fluid WT, thereby suppressing defects such as corrosion of the plurality of assembly lines AL and the plurality of assembly electrodes AE.

The passivation layer 12 may be formed of, for example, an oxide or a nitride, and may be formed of a single layer or multiple layers of silicon oxide (SiOx) or silicon nitride (SiNx), but is not limited thereto.

Next, an insulating layer 13 including a plurality of openings 13H, a first wiring line 14, a second wiring line 15, and a plurality of coils 19 are disposed on the passivation layer 12.

Referring to FIG. 2, the plurality of coils 19 may be disposed so as to enclose the plurality of openings 13H.

The plurality of coils 19 may be formed of a conductive material, for example, copper (Cu), aluminum (Al), molybdenum (Mo), nickel (Ni), titanium (Ti), chromium (Cr), or an alloy thereof, but is not limited thereto.

Each of the plurality of coils 19 may include a plurality of coil electrodes. For example, the coil 19 may enclose the opening 13H and may include a plurality of coil electrodes spaced apart from the opening 13H at different intervals. For example, referring to FIG. 2, one coil 19 may include a first coil electrode 19a enclosing one opening 13H, a second coil electrode 19b enclosing the first coil electrode 19a, and a third coil electrode 19c enclosing the second coil electrode 19b. Meanwhile, although only the first coil electrode 19a, the second coil electrode 19b, and the third coil electrode 19c are illustrated in FIGS. 2 and 3, the number of coil electrodes constituting the coil 19 is not limited thereto. In addition, although in the present disclosure one coil 19 is described as enclosing one opening 13H, the present disclosure is not limited thereto. For example, one coil 19 may enclose at least two of the plurality of openings 13H.

Each planar shape of the first coil electrode 19a, the second coil electrode 19b, and the third coil electrode 19c may be identical to each other. At this time, the planar shapes of the first coil electrode 19a, the second coil electrode 19b, and the third coil electrode 19c may be different from the planar shape of the opening 13H. For example, the planar shape of the opening 13H may be circular, but each of the first coil electrode 19a, the second coil electrode 19b, and the third coil electrode 19c may extend in a straight shape to enclose the plurality of openings 13H. Meanwhile, the planar shapes of the first coil electrode 19a, the second coil electrode 19b, and the third coil electrode 19c illustrated in FIG. 2 and the planar shape of the opening 13H are merely exemplary, and the present disclosure is not limited thereto. For example, the planar shape of the opening 13H may be an ellipse, and each of the first coil electrode 19a, the second coil electrode 19b, and the third coil electrode 19c may be a polygonal shape.

The interval between adjacent coil electrodes among the plurality of coils 19 may be identical to each other. For example, the interval between the first coil electrode 19a and the second coil electrode 19b, and the interval between the second coil electrode 19b and the third coil electrode 19c may be identical.

On a plane, the center of the first coil electrode 19a, the center of the second coil electrode 19b, and the center of the third coil electrode 19c may coincide with each other. For example, the center of the first coil electrode 19a, the center of the second coil electrode 19b, and the center of the third coil electrode 19c may coincide with the center of the opening 13H, but the present disclosure is not limited thereto.

Referring also to FIG. 3, the first coil electrode 19a, the second coil electrode 19b, and the third coil electrode 19c may be disposed on the same layer, and the first coil electrode 19a, the second coil electrode 19b, and the third coil electrode 19c may be connected to each other in the same layer. For example, one end of the second coil electrode 19b may be connected to the other end of the third coil electrode 19c, and the other end of the second coil electrode 19b may be connected to one end of the first coil electrode 19a.

At this time, one end of the third coil electrode 19c may be connected to the first wiring line 14 described below, and the other end of the first coil electrode 19a may be connected to the second wiring line 15 described below.

The first wiring line 14 may be disposed on the passivation layer 12. The first wiring line 14 is connected to one end of the plurality of coils 19 so that a voltage may be applied to the plurality of coils 19. For example, the first wiring line 14 may be connected to one end of the third coil electrode 19c. At this time, when one end of the third coil electrode 19c is disposed adjacent to one side of the opening 13H between one side of the opening 13H where the first assembly line AL1 is disposed and the other side of the opening 13H where the second assembly line AL2 is disposed, the first wiring line 14 may be disposed adjacent to one side of the opening 13H and connected to one end of the third coil electrode 19c.

Meanwhile, the position of the first wiring line 14 illustrated in FIG. 2 is merely exemplary, and the present disclosure is not limited thereto, and the position of the first wiring line 14 may vary according to the position where one end of the plurality of coils 19 is disposed.

The first wiring line 14 may be disposed on the same layer as the plurality of coils 19 and connected to the plurality of coils 19. For example, the plurality of coils 19 may be an extended portion from the first wiring line 14. Specifically, the third coil electrode 19c of the plurality of coils 19 may be disposed on the same layer as the first wiring line 14 and may be an extended portion from the first wiring line 14, but the present disclosure is not limited thereto.

The first wiring line 14 may be formed of the same material as the plurality of coils 19. The first wiring line 14 may be formed of a conductive material, for example, copper (Cu), aluminum (Al), molybdenum (Mo), nickel (Ni), titanium (Ti), chromium (Cr), or an alloy thereof, but is not limited thereto.

A plurality of insulating layers 13 may be disposed on the plurality of coils 19 and the first wiring line 14. The plurality of insulating layers 13 may be disposed to enclose the plurality of coils 19. For example, the plurality of insulating layers 13 may cover the side surface and the top surface of the plurality of coils 19.

The plurality of insulating layers 13 includes a plurality of openings 13H. Each of the plurality of openings 13H formed by opening a portion of the plurality of insulating layers 13 is an area in which a plurality of light emitting diodes is self-assembled. The plurality of openings 13H may be disposed to overlap an area between the first assembly electrode AE1 and the second assembly electrode AE2.

The plurality of openings 13H may have a shape corresponding to a planar shape of the plurality of light emitting diodes. Therefore, by forming the shape of the plurality of openings 13H to correspond to the shape of the plurality of light emitting diodes, only light emitting diodes having a specific shape may be self-assembled in each of the openings 13H.

Referring to FIG. 3, the plurality of insulating layers 13 may include a first insulating layer 13a and a second insulating layer 13b. The first insulating layer 13a is disposed on the plurality of assembly lines AL, and the second insulating layer 13b is disposed on the first insulating layer 13a.

First, the first insulating layer 13a is disposed on the plurality of coils 19 and the passivation layer 12. The first insulating layer 13a may be disposed to cover the top surface and side surface of the plurality of coils 19 and the top surface and side surface of the first wiring line 14. In addition, the first insulating layer 13a may cover the top surface of the passivation layer 12 exposed from the plurality of coils 19 and the first wiring line 14.

The first insulating layer 13a may be formed of an inorganic material such as silicon oxide (SiOx) or silicon nitride (SiNx), or may be formed of an organic material such as photoresist or acryl-based material, but is not limited thereto.

The first insulating layer 13a may include a plurality of contact holes for connecting the second wiring line 15 and the plurality of coils 19. Accordingly, the second wiring line 15 may be connected to the plurality of coils 19 through the plurality of contact holes of the first insulating layer 13a.

The second wiring line 15 may be disposed on the first insulating layer 13a. The second wiring line 15 is connected to the other end of the plurality of coils 19 so that a voltage may be applied to the plurality of coils 19. For example, the second wiring line 15 may be connected to the other end of the first coil electrode 19a. At this time, when the other end of the first coil electrode 19a is disposed adjacent to the other side of the opening 13H between one side of the opening 13H where the first assembly line AL1 is disposed and the other side of the opening 13H where the second assembly line AL2 is disposed, the second wiring line 15 may be disposed adjacent to the other side of the opening 13H and connected to the other end of the first coil electrode 19a.

At this time, the second wiring line 15 may be disposed so as not to overlap with the first wiring line 14. For example, the second wiring line 15 may be disposed on a plane so as to be spaced apart from the first wiring line 14 with the plurality of openings 13H interposed therebetween. Specifically, as illustrated in FIG. 2, the first wiring line 14 may be disposed adjacent to one side of the opening 13H where the first assembly line AL1 is disposed, and the second wiring line 15 may be disposed adjacent to the other side of the opening 13H where the second assembly line AL2 is disposed, but the present disclosure is not limited thereto. That is, the position of the second wiring line 15 illustrated in FIG. 2 is merely exemplary, and the present disclosure is not limited thereto, and the position of the second wiring line 15 may vary according to the position where the other end of the plurality of coils 19 is disposed.

The second wiring line 15 may be formed of a conductive material. For example, the second wiring line 15 may be formed of copper (Cu), aluminum (Al), molybdenum (Mo), nickel (Ni), titanium (Ti), chromium (Cr), or an alloy thereof, which is the same as the first wiring line 14, but is not limited thereto.

Referring to FIG. 3, the second insulating layer 13b is disposed on the first insulating layer 13a and the second wiring line 15. The second insulating layer 13b may be disposed to cover the top surface and side surface of the second wiring line 15.

The second insulating layer 13b may be formed of an inorganic material such as silicon oxide (SiOx) or silicon nitride (SiNx), or may be formed of an organic material such as photoresist or acryl-based material. In addition, the second insulating layer 13b may be formed of the same material as the first insulating layer 13a, but is not limited thereto.

A protective layer IL is disposed on the plurality of insulating layers 13. For example, the protective layer IL may cover the side surface of the first insulating layer 13a, the side surface of the second insulating layer 13b, and the top surface of the second insulating layer 13b. In addition, the protective layer IL may cover the top surface of the passivation layer 12 exposed in the opening 13H to protect the plurality of assembly lines AL, the plurality of assembly electrodes AE, and the insulating layer 13 from the fluid WT, thereby suppressing defects such as corrosion of the plurality of assembly lines AL.

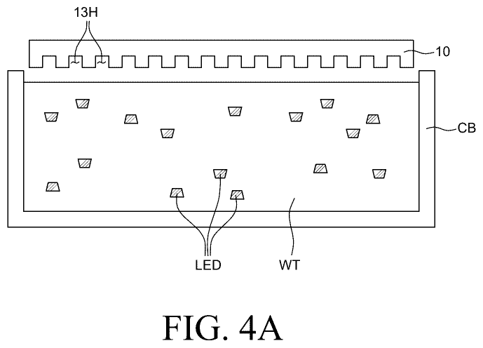

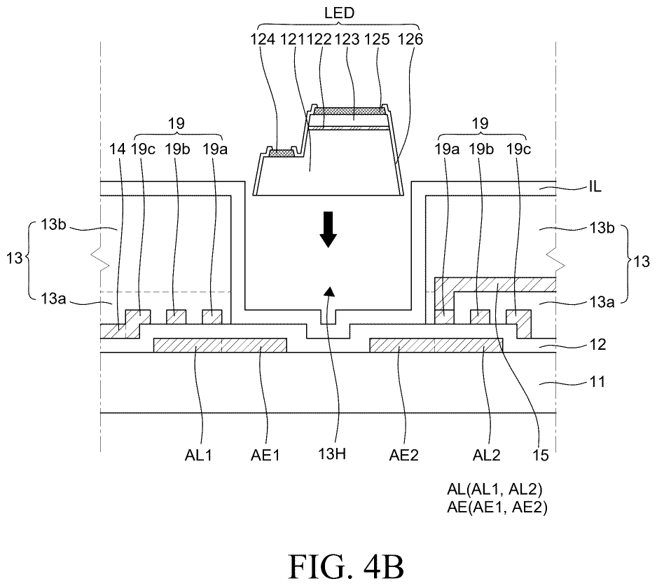

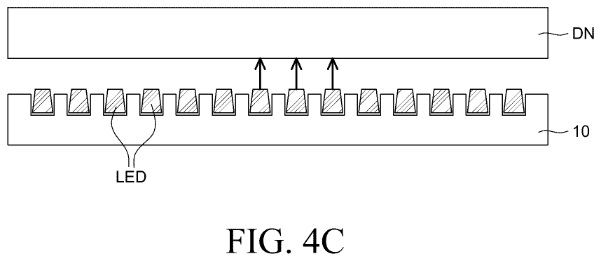

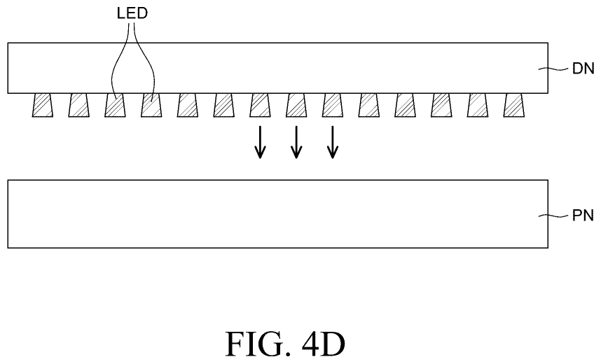

Hereinafter, with reference to FIGS. 4A to 4D, a method of manufacturing a display device using the assembly substrate 10 according to an exemplary embodiment of the present disclosure will be described.

FIGS. 4A to 4D are process diagrams for explaining a method of manufacturing a display device using the assembly substrate according to an exemplary embodiment of the present disclosure. FIGS. 4A and 4B are views for explaining a process of self-assembling a light emitting diode (LED) on the assembly substrate 10. FIG. 4C is a view for explaining a process of transferring the light emitting diode LED on the assembly substrate 10 to a donor DN. FIG. 4D is a view for explaining a process of transferring the light emitting diode LED on the donor DN to a display panel PN.

Referring to FIG. 4A, a plurality of light emitting diodes LED is self-assembled on the assembly substrate 10.

First, a plurality of light emitting diodes LED grown on a wafer is introduced into a chamber CB filled with a fluid WT. The fluid WT may include water and the chamber CB filled with the fluid WT may have a shape in which an upper portion is open.

At this time, the light emitting diode LED may include a magnetic material so as to be moved by a magnetic field. For example, the light emitting diode LED may include a first semiconductor layer 121, an emission layer 122, a second semiconductor layer 123, a first electrode 124, a second electrode 125, and an encapsulation film 126, and any one of the first electrode 124 or the second electrode 125 of the light emitting diode LED may include a ferromagnetic material. For example, the second electrode 125 may include a ferromagnetic material such as nickel (Ni) and cobalt (Co).

Specifically, referring also to FIG. 4B, the second semiconductor layer 123 is disposed on the first semiconductor layer 121. The first semiconductor layer 121 and the second semiconductor layer 123 may be layers formed by doping n-type and p-type impurities into a specific material. For example, each of the first semiconductor layer 121 and the second semiconductor layer 123 may be a layer doped with n-type and p-type impurities in materials such as aluminum gallium indium phosphide (AlGaInP), indium aluminum phosphide (InAlP), gallium arsenide (GaAs), or gallium nitride (GaN). The p-type impurity may be magnesium, zinc (Zn), or beryllium (Be), and the n-type impurity may be silicon (Si), germanium, or tin (Sn), but is not limited thereto.

The first electrode 124 is disposed on the first semiconductor layer 121. The first electrode 124 may be disposed on the top surface of the first semiconductor layer 121 exposed from the emission layer 122 and the second semiconductor layer 123. The first electrode 124 may be formed of a conductive material, for example, a transparent conductive material such as indium tin oxide (ITO) or indium zinc oxide (IZO), or an opaque conductive material such as titanium (Ti), gold (Au), silver (Ag), copper (Cu), or an alloy thereof, but is not limited thereto.

The second electrode 125 is disposed on the second semiconductor layer 123. The second electrode 125 may be disposed on the top surface of the second semiconductor layer 123. The second electrode 125 may be formed of a conductive material, for example, a transparent conductive material such as indium tin oxide (ITO) or indium zinc oxide (IZO), or an opaque conductive material such as titanium (Ti), gold (Au), silver (Ag), copper (Cu), or an alloy thereof, but is not limited thereto.

At this time, any one of the first electrode 124 or the second electrode 125 may include a ferromagnetic material. For example, the second electrode 125 may include a ferromagnetic material such as nickel (Ni) and cobalt (Co).

Next, an encapsulation film 126 enclosing the first semiconductor layer 121, the emission layer 122, the second semiconductor layer 123, the first electrode 124, and the second electrode 125 is disposed. The encapsulation film 126 is formed of an insulating material and may protect the first semiconductor layer 121, the emission layer 122, and the second semiconductor layer 123. The encapsulation film 126 has contact holes exposing the first electrode 124 and the second electrode 125 so that the light emitting diode LED may be electrically connected to the display panel.

FIG. 4B illustrates a state in which the assembly substrate 10 is immersed in the chamber CB filled with the fluid WT and is disposed upside down relative to FIG. 4A for clarity.

Thereafter, the assembly substrate 10 may be positioned in the chamber CB filled with the light emitting diodes LED. The assembly substrate 10 having the plurality of openings 13H may be disposed so as to face the chamber CB.

Next, a voltage is applied to the first wiring line 14 and the second wiring line 15 of the assembly substrate 10. A direct current may flow in the plurality of coils 19. For example, a current may flow in the plurality of coils 19 from one end of the first coil electrode 19a connected to the second wiring line 15 to the other end of the third coil electrode 19c connected to the first wiring line 14.

At this time, since the plurality of coils 19 is disposed so as to enclose the plurality of openings 13H, a magnetic field may be formed in the plurality of openings 13H according to the right-hand rule of Ampere. Accordingly, the light emitting diodes LED sunk to the bottom of or floating in the chamber CB may move toward the assembly substrate 10 by the magnetic field formed in the plurality of openings 13H.

The light emitting diodes LED moved toward the assembly substrate 10 by the current flowing in the plurality of coils 19 may be self-assembled on the assembly substrate 10 by the electric field formed between the plurality of assembly electrodes AE.

Specifically, by applying a voltage to the plurality of assembly lines AL and the plurality of assembly electrodes AE, a plurality of light emitting diodes LED may be self-assembled in the openings 13H of the insulating layer 13. For example, different alternating voltages are applied to the plurality of first assembly lines AL1 and the plurality of first assembly electrodes AE1, and the plurality of second assembly lines AL2 and the plurality of second assembly electrodes AE2, so that an electric field may be formed. By the electric field, the light emitting diode LED may be dielectrically polarized and have polarity. The dielectrically polarized light emitting diode LED may move or be fixed in a specific direction by dielectrophoresis (DEP), that is, by an electric field. Therefore, using dielectrophoresis, a plurality of light emitting diodes LED may be temporarily self-assembled inside the openings 13H of the assembly substrate 10.

After the self-assembly is completed, the fluid WT may be evaporated from the assembly substrate 10. At this time, until the fluid WT is completely evaporated, an electric field is formed between the assembly electrodes AE so that the light emitting diode LED may be fixed inside the opening 13H. When drying of the assembly substrate 10 is completed, the electric field may be removed. Even after the electric field is removed, the light emitting diode LED may be temporarily fixed to the assembly substrate 10 through a van der Waals force.

Next, referring to FIG. 4C, the plurality of light emitting diodes LED of the assembly substrate 10 is transferred to a donor DN.

First, the assembly substrate 10 and the donor DN are aligned so that the plurality of light emitting diodes LED and the donor DN face each other. After aligning the assembly substrate 10 and the donor DN, the assembly substrate 10 and the donor DN are attached to each other so that the upper portion of the light emitting diode LED contacts the donor DN. Since the donor DN is formed of a material having adhesiveness, the upper portion of the plurality of light emitting diodes LED is adhered to the donor DN, and the plurality of light emitting diodes LED may move from the assembly substrate 10 to the donor DN.

The donor DN may be formed of a polymer material having viscoelasticity, for example, poly dimethyl siloxane (PDMS), poly urethane acrylate (PUA), polyethylene glycol (PEG), poly methyl meth acrylate (PMMA), poly styrene (PS), epoxy resin, urethane resin, or acryl resin, but is not limited thereto.

Next, referring to FIG. 4D, the plurality of light emitting diodes LED on the donor DN is transferred onto the display panel PN. Here, the display panel PN may mean a configuration including a driving circuit and a plurality of wiring lines for driving the plurality of light emitting diodes LED.

First, the display panel PN and the donor DN are aligned. After disposing the donor DN such that the plurality of light emitting diodes LED of the donor DN faces the display panel PN, the display panel PN and the donor DN may be aligned.

Meanwhile, one surface of the display panel PN to which the plurality of light emitting diodes LED is attached may include an adhesive layer for attaching the plurality of light emitting diodes LED, but is not limited thereto.

In order to transfer the plurality of light emitting diodes LED to the display panel, after self-assembling the plurality of light emitting diodes LED on the assembly substrate in a disposition corresponding to the plurality of sub pixels, the plurality of light emitting diodes LED on the assembly substrate may be transferred to the display panel by using the donor. At this time, in order to assemble the plurality of light emitting diodes LED dispersed in the fluid into the plurality of openings of the assembly substrate, a process of guiding the plurality of light emitting diodes LED toward the assembly substrate is performed.

Accordingly, the assembly substrate 10 according to an exemplary embodiment of the present disclosure includes the plurality of coils 19 enclosing the plurality of openings 13H in the assembly substrate 10 in order to move the plurality of light emitting diodes LED toward the plurality of openings 13H of the assembly substrate 10. When a current is applied to the plurality of coils 19, a magnetic field may be formed in the plurality of openings 13H according to the right-hand rule of Ampere. Therefore, the plurality of light emitting diodes LED including a magnetic material may move toward the plurality of openings 13H by the magnetic field formed in the plurality of openings 13H and may be temporarily fixed inside the plurality of openings 13H.

Therefore, the assembly substrate 10 according to an exemplary embodiment of the present disclosure may omit a process of forming a magnetic field separately from outside in order to guide the plurality of light emitting diodes LED toward the plurality of openings 13H of the assembly substrate 10. For example, the assembly substrate 10 may not require a process of disposing a magnet on the rear surface of the assembly substrate 10 to guide the plurality of light emitting diodes LED toward the plurality of openings 13H, and the plurality of light emitting diodes LED may be assembled without a separate magnet. Accordingly, the process of assembling the plurality of light emitting diodes LED may be simplified, and the magnetic field may be formed only in a portion where assembly is required, thereby improving self-assembly efficiency, facilitating the manufacturing process of the display device, and improving production efficiency. In addition, since the plurality of light emitting diodes LED may be assembled only by applying a current to each of the plurality of coils 19, the plurality of light emitting diodes LED may be easily assembled on a large-area assembly substrate 10, and process optimization may be implemented.

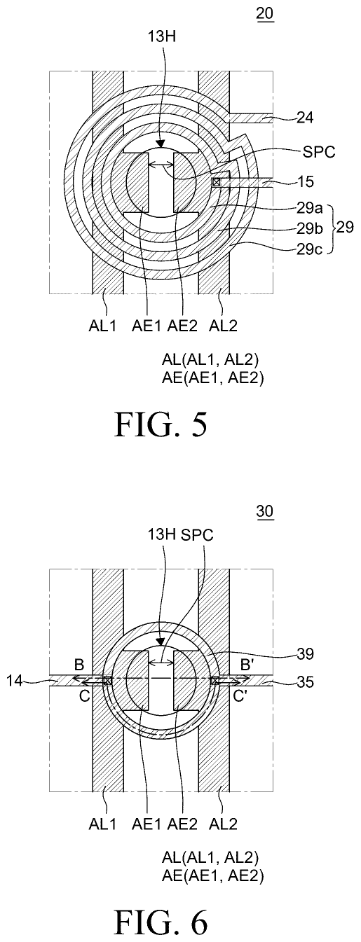

FIG. 5 is an enlarged plan view of an assembly area of an assembly substrate according to another exemplary embodiment of the present disclosure. An assembly substrate 20 of FIG. 5 differs from the assembly substrate 10 of FIGS. 1 and 3 only in that it includes the plurality of coils 29 and the first wiring line 24, and other configurations are substantially the same, and thus a redundant description thereof will be omitted.

Referring to FIG. 5, the plurality of coils 29 enclosing the plurality of openings 13H may be disposed on the passivation layer 12. At this time, the planar shape of the plurality of coils 29 may correspond to the planar shape of the plurality of openings 13H. For example, when the planar shape of the plurality of openings 13H is circular, the planar shape of the plurality of coils 29 may be in the form of a ring enclosing the circle.

Each of the plurality of coils 29 may include a first coil electrode 29a, a second coil electrode 29b, and a third coil electrode 29c.

Each planar shape of the first coil electrode 29a, the second coil electrode 29b, and the third coil electrode 29c may be identical to each other. For example, each of the first coil electrode 29a, the second coil electrode 29b, and the third coil electrode 29c may extend in a curved shape to enclose the plurality of openings 13H. At this time, an interval between adjacent coil electrodes may be identical to each other. For example, the interval between the first coil electrode 29a and the second coil electrode 29b, and the interval between the second coil electrode 29b and the third coil electrode 29c may be identical.

At this time, on a plane, the center of the first coil electrode 19a, the center of the second coil electrode 19b, and the center of the third coil electrode 19c may coincide with each other. For example, the centers of the first coil electrode 19a, the second coil electrode 19b, and the third coil electrode 19c may coincide with the center of the opening 13H, but the present disclosure is not limited thereto.

Meanwhile, the first coil electrode 29a, the second coil electrode 29b, and the third coil electrode 29c may be disposed on the same layer, and the first coil electrode 29a, the second coil electrode 29b, and the third coil electrode 29c may be connected to each other in the same layer.

One end of the plurality of coils 29 may be connected to the first wiring line 24 on the passivation layer 12. The first wiring line 24 may extend in the same direction as the second wiring line 15 and may be disposed so as not to overlap with the second wiring line 15. For example, as illustrated in FIG. 4, the first wiring line 24 and the second wiring line 15 may extend to the other side of the opening 13H where the second assembly line AL2 is disposed, but the present disclosure is not limited thereto.

The assembly substrate 20 according to another exemplary embodiment of the present disclosure applies a current to the plurality of coils 29 enclosing the plurality of openings 13H in the assembly substrate 20 in order to move the plurality of light emitting diodes LED toward the plurality of openings 13H of the assembly substrate 20. Accordingly, a magnetic field may be formed in the plurality of openings 13H enclosed by the plurality of coils 29, and the plurality of light emitting diodes LED may be assembled on the assembly substrate 20 without a separate magnet, thereby facilitating the manufacturing process of the display device and improving production efficiency.

The assembly substrate 20 according to another exemplary embodiment of the present disclosure disposes the plurality of coils 29 so that a planar shape of the plurality of coils 29 corresponds to a planar shape of the plurality of openings 13H. Accordingly, the centers of the plurality of coil electrodes constituting the plurality of coils 29 may coincide with the centers of the plurality of openings 13H, and the magnetic field for assembling the plurality of light emitting diodes LED onto the assembly substrate 20 may be concentrated and formed inside the openings 13H. Therefore, the plurality of light emitting diodes LED may be easily assembled on the assembly substrate 20, and the manufacturing process of the display device may be facilitated to improve production efficiency.

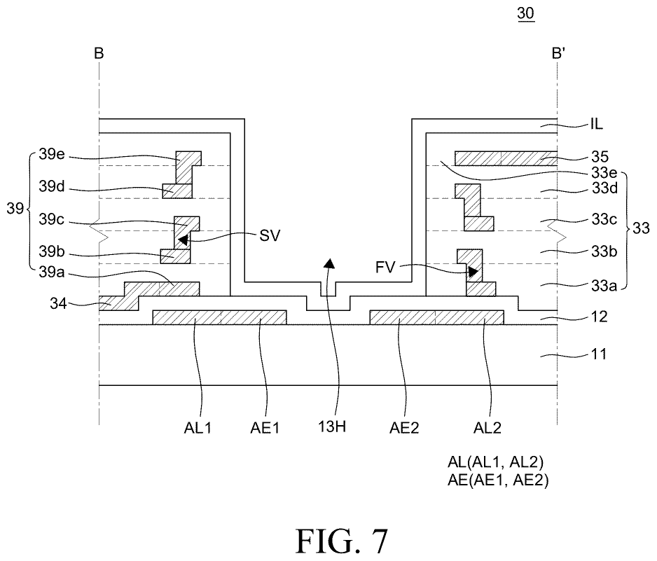

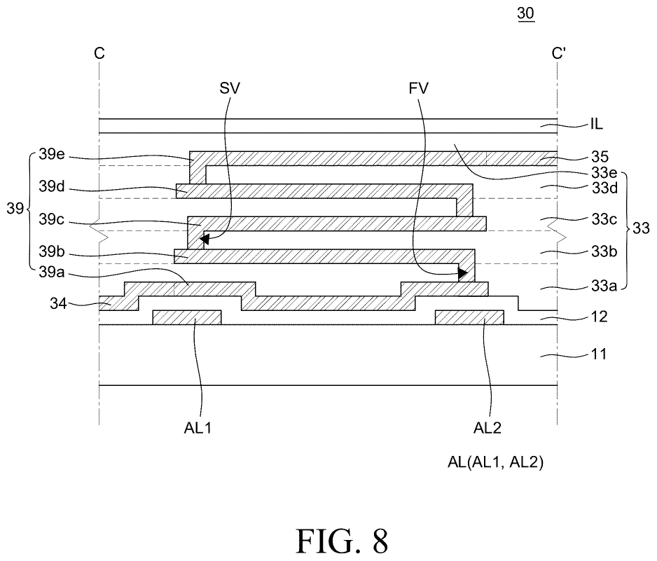

FIG. 6 is an enlarged plan view of an assembly area of an assembly substrate according to still another exemplary embodiment of the present disclosure. FIG. 7 is a cross-sectional view taken along B-B′ of FIG. 6. FIG. 8 is a cross-sectional view taken along C-C′ of FIG. 6. An assembly substrate 30 of FIG. 6 differs from the assembly substrate 10 of FIGS. 1 and 3 in that it includes the plurality of coils 39 and the plurality of insulating layers 33, and other configurations are substantially the same, and thus a redundant description thereof will be omitted.

Referring to FIGS. 7 and 8, the plurality of coils 39 and the plurality of insulating layers 33 enclosing the plurality of coils 39 are disposed on the passivation layer 12.

Each of the plurality of coils 39 may include a plurality of coil electrodes enclosing the opening 13H. Each of the plurality of coil electrodes may be spaced apart from the opening 13H at the same interval. For example, each of the plurality of coil electrodes may be disposed so as to overlap each other in different layers. Specifically, referring to FIGS. 6 to 8, one coil 39 may enclose one opening 13H and may include the first coil electrode 39a, the second coil electrode 39b, the third coil electrode 39c, the fourth coil electrode 39d, and the fifth coil electrode 39e overlapping each other. Accordingly, centers of the first coil electrode 39a, the second coil electrode 39b, the third coil electrode 39c, the fourth coil electrode 39d, and the fifth coil electrode 39e may coincide with each other and also coincide with the center of the opening 13H.

Referring to FIGS. 7 and 8, the first coil electrode 39a may be disposed on the passivation layer 12, the second coil electrode 39b may be disposed on the first coil electrode 39a, the third coil electrode 39c may be disposed on the second coil electrode 39b, the fourth coil electrode 39d may be disposed on the third coil electrode 39c, and the fifth coil electrode 39e may be disposed on the fourth coil electrode 39d.

Each of the first coil electrode 39a, the second coil electrode 39b, the third coil electrode 39c, the fourth coil electrode 39d, and the fifth coil electrode 39e may have a closed-loop shape enclosing one opening 13H.

The plurality of coil electrodes may be disposed on different layers with the plurality of insulating layers 33 interposed therebetween and may be connected to each other through contact holes of the plurality of insulating layers 33. For example, referring to FIGS. 7 and 8, the plurality of insulating layers 33 may include a first insulating layer 33a disposed on the passivation layer 12, a second insulating layer 33b disposed on the first insulating layer 33a, a third insulating layer 33c disposed on the second insulating layer 33b, a fourth insulating layer 33d disposed on the third insulating layer 33c, and a fifth insulating layer 33e disposed on the fourth insulating layer 33d.

Specifically, referring to FIGS. 7 and 8, the first insulating layer 33a may be disposed between the first coil electrode 39a and the second coil electrode 39b. At this time, the first coil electrode 39a and the second coil electrode 39b may be connected through a contact hole of the first insulating layer 33a. Next, the second insulating layer 33b may be disposed between the second coil electrode 39b and the third coil electrode 39c. The second coil electrode 39b and the third coil electrode 39c may be connected through a contact hole of the second insulating layer 33b. At this time, the contact hole of the second insulating layer 33b may not overlap the contact hole of the first insulating layer 33a, but the present disclosure is not limited thereto. Next, the third insulating layer 33c may be disposed between the third coil electrode 39c and the fourth coil electrode 39d. The third coil electrode 39c and the fourth coil electrode 39d may be connected through a contact hole of the third insulating layer 33c. At this time, the contact hole of the third insulating layer 33c may overlap the contact hole of the first insulating layer 33a, but the present disclosure is not limited thereto. Next, the fourth insulating layer 33d may be disposed between the fourth coil electrode 39d and the fifth coil electrode 39e. The fourth coil electrode 39d and the fifth coil electrode 39e may be connected through a contact hole of the fourth insulating layer 33d. At this time, the contact hole of the fourth insulating layer 33d may overlap the contact hole of the second insulating layer 33b, but the present disclosure is not limited thereto.

Next, the fifth insulating layer 33e is disposed on the fifth coil electrode 39e so as to cover the top surface and the side surface of the fifth coil electrode 39e.

Meanwhile, although only the first coil electrode 39a, the second coil electrode 39b, the third coil electrode 39c, the fourth coil electrode 39d, and the fifth coil electrode 39e are illustrated in FIGS. 6 to 8, the number of coil electrodes constituting the coil 39 is not limited thereto.

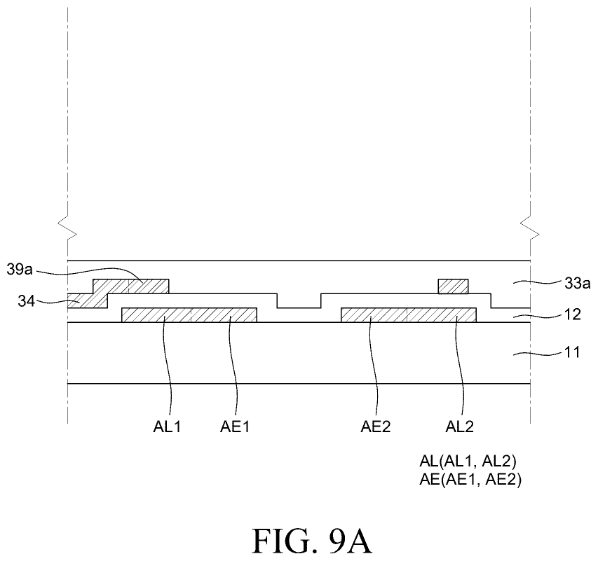

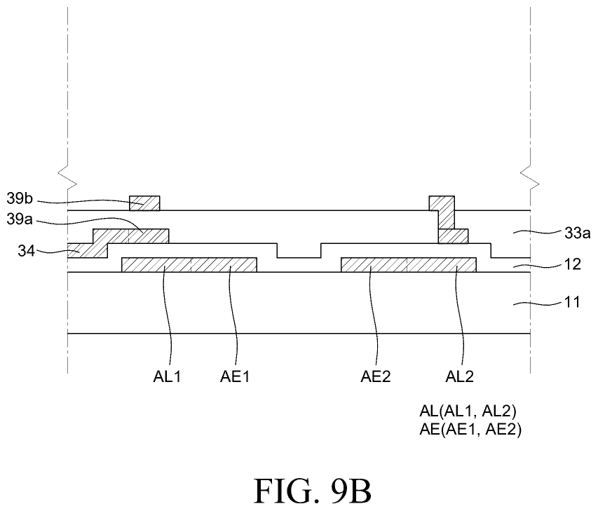

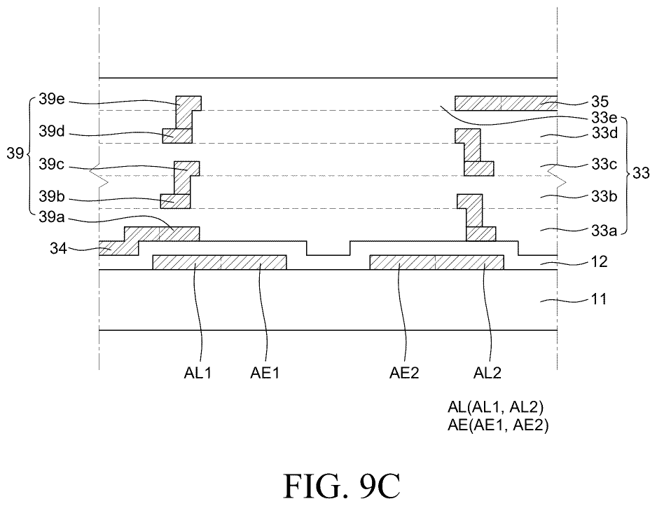

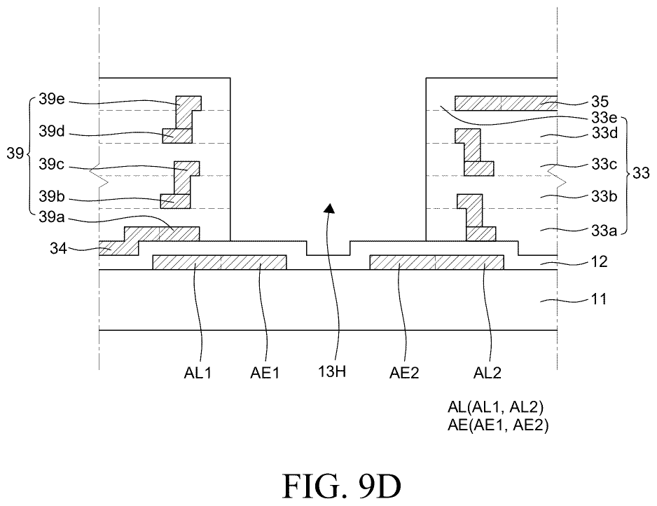

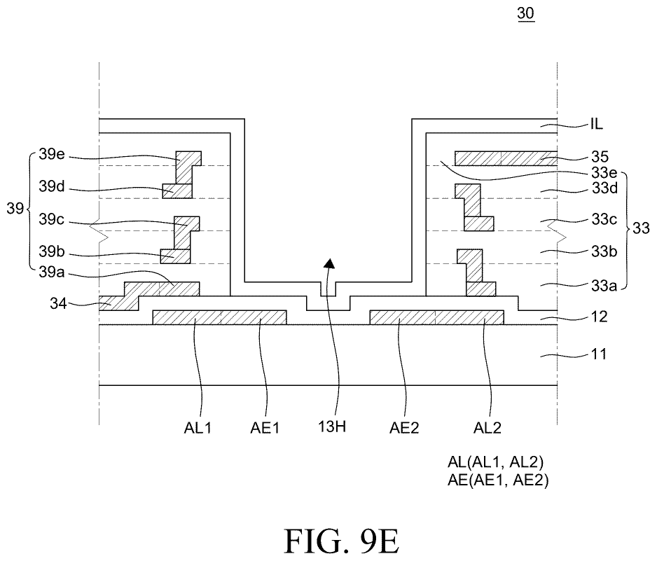

Hereinafter, with reference to FIGS. 9A to 9E, a method of manufacturing the assembly substrate 30 of FIGS. 6 to 8 will be described.

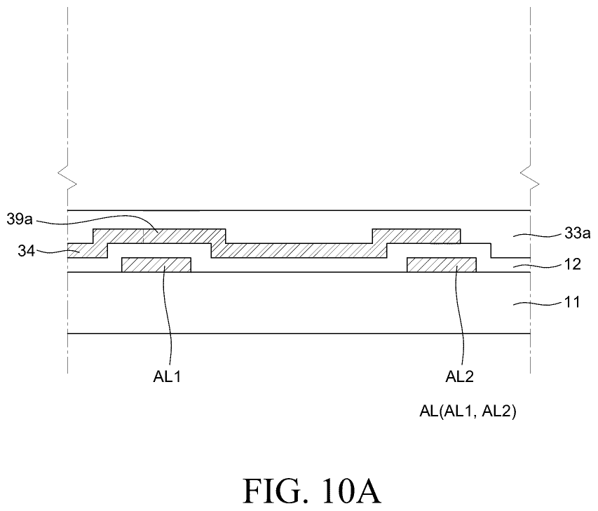

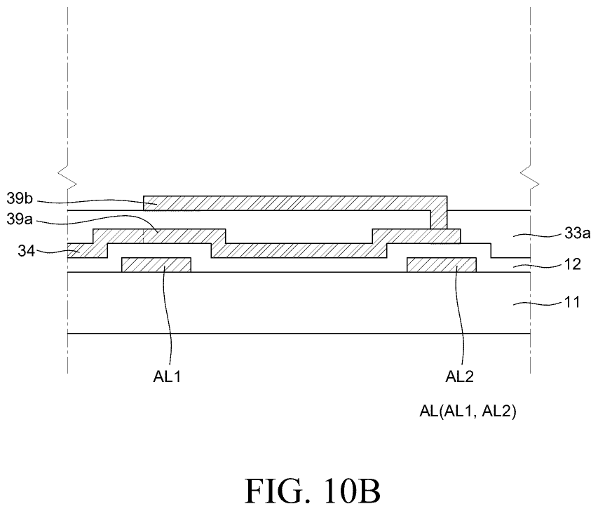

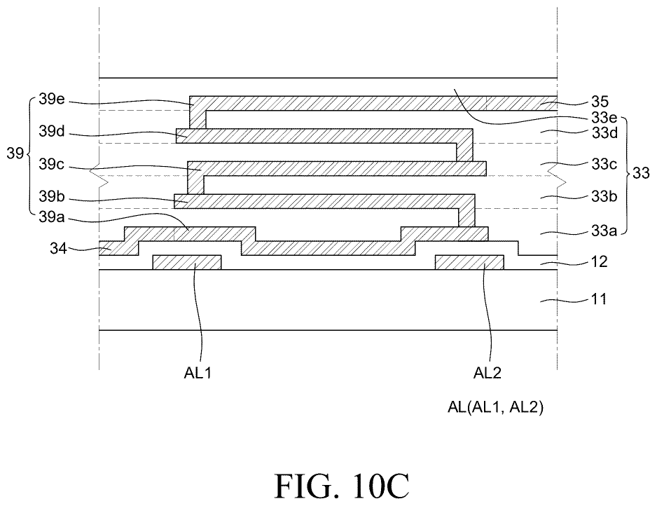

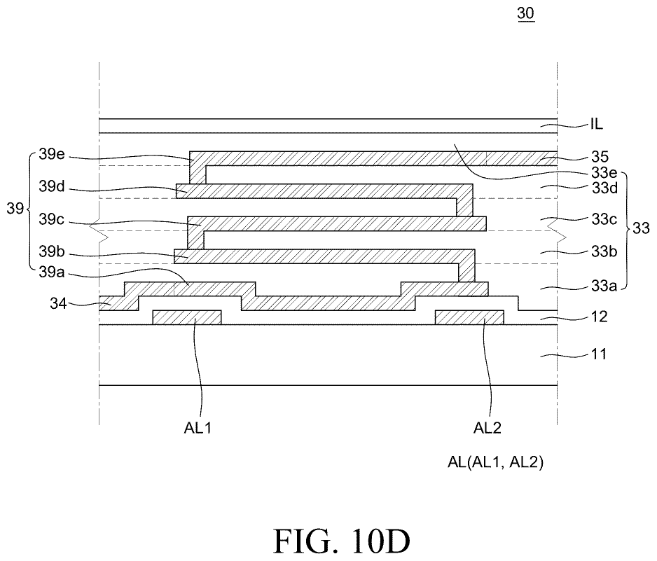

FIGS. 9A to 10D are process diagrams for explaining a method of manufacturing an assembly substrate according to still another exemplary embodiment of the present disclosure. Specifically, FIGS. 9A to 10D are process diagrams for explaining a method of manufacturing the assembly substrate 30 of FIGS. 6 to 8. FIGS. 9A to 9E are process diagrams for an area corresponding to FIG. 7. FIGS. 10A to 10D are process diagrams for an area corresponding to FIG. 8. FIGS. 9A and 10A are views of the same process, FIGS. 9B and 10B are views of the same process, FIGS. 9C and 10C are views of the same process, and FIGS. 9E and 10D are views of the same process.

Referring to FIGS. 9A and 10A, a passivation layer 12 is formed on the assembly base substrate 11 on which the plurality of first assembly electrodes AE1, the plurality of second assembly electrodes AE2, the plurality of first assembly lines AL1, and the plurality of second assembly lines AL2 are formed, and the first coil electrode 39a and the first insulating layer 33a covering the first coil electrode 39a are formed on the passivation layer 12.

The first coil electrode 39a may be disposed so as to enclose an area where the opening 13H to be described later is to be formed. For example, the opening 13H may correspond to the planar shape of the light emitting diode LED. Accordingly, when the planar shape of the light emitting diode LED is circular, the first coil electrode 39a may be disposed in the form of a ring enclosing the circle. Next, the first insulating layer 33a covering the first coil electrode 39a is formed.

Next, referring to FIGS. 9B and 10B, a contact hole is formed in the first insulating layer 33a, and the second coil electrode 39b is formed on the first insulating layer 33a having the contact hole. The contact hole of the first insulating layer 33a is formed in an area overlapping the first coil electrode 39a. Accordingly, the first coil electrode 39a and the second coil electrode 39b are in contact with each other through the contact hole of the first insulating layer 33a and may be electrically connected.

Thereafter, as in the process described with reference to FIGS. 9B and 10B, after forming an insulating layer covering one coil electrode, a contact hole is formed in the insulating layer, and another coil electrode filling the contact hole is formed. This process may be repeated. Accordingly, as illustrated in FIGS. 9C and 10C, the second insulating layer 33b on the second coil electrode 39b and the third coil electrode 39c connected to the second coil electrode 39b through the contact hole of the second insulating layer 33b may be formed. In addition, the third insulating layer 33c on the third coil electrode 39c and the fourth coil electrode 39d connected to the third coil electrode 39c through the contact hole of the third insulating layer 33c may be formed. Furthermore, the fourth insulating layer 33d on the fourth coil electrode 39d and the fifth coil electrode 39e connected to the fourth coil electrode 39d through the contact hole of the fourth insulating layer 33d may be formed, thereby completing the process of forming the plurality of coils 39.

In addition, the fifth insulating layer 33e covering the fifth coil electrode 39e and planarizing the upper portions of the plurality of coils 39 may be formed.

Next, referring to FIG. 9D, a portion of the plurality of insulating layers 33 enclosed by the plurality of coils 39 is removed to form the opening 13H. For example, the plurality of insulating layers 33 may be removed so that the top surface of the passivation layer 12 overlapping the first assembly electrode AE1 and the second assembly electrode AE2 is exposed, thereby forming the opening 13H.

Thereafter, referring to FIGS. 9E and 10D, a protective layer IL is formed to cover the top surface of the passivation layer 12 exposed by the opening 13H and the side surface and the top surface of the plurality of insulating layers 33, in order to suppress defects such as corrosion of the plurality of assembly lines AL and the plurality of assembly electrodes AE.

The assembly substrate 30 according to still another exemplary embodiment of the present disclosure applies a current to the plurality of coils 39 enclosing the plurality of openings 13H in the assembly substrate 30 in order to move the plurality of light emitting diodes LED toward the plurality of openings 13H of the assembly substrate 30. Accordingly, a magnetic field may be formed in the plurality of openings 13H enclosed by the plurality of coils 39, and the plurality of light emitting diodes LED may be assembled on the assembly substrate 30 without a separate magnet, thereby facilitating the manufacturing process of the display device and improving production efficiency.

The assembly substrate 30 according to still another exemplary embodiment of the present disclosure disposes the plurality of coils 39 so that a planar shape of the plurality of coils 39 corresponds to a planar shape of the plurality of openings 13H. Accordingly, the center of each of the plurality of coil electrodes constituting the plurality of coils 39 may coincide with the center of each of the plurality of openings 13H, and the magnetic field for assembling the plurality of light emitting diodes LED onto the assembly substrate 30 may be concentrated and formed inside the openings 13H. Therefore, the plurality of light emitting diodes LED may be easily assembled on the assembly substrate 30, and the manufacturing process of the display device may be facilitated to improve production efficiency.

The assembly substrate 30 according to still another exemplary embodiment of the present disclosure includes the plurality of coil electrodes in which the plurality of coils 39 are sequentially stacked on the assembly base substrate 11, thereby improving the strength of the magnetic field formed inside the opening 13H. For example, when the plurality of coils 39 overlaps each other and includes the plurality of coil electrodes sequentially stacked, each of the coil electrodes may be spaced apart from the opening 13H by the same interval and may be disposed spaced apart from the opening 13H by a minimum interval. Accordingly, since each of the plurality of coil electrodes enclosing the opening 13H is disposed spaced apart from the opening 13H by the minimum interval, the strength of the magnetic field formed inside the opening 13H may be improved, and the plurality of light emitting diodes LED may be more easily assembled on the assembly substrate 30. Therefore, the manufacturing process of the display device may be facilitated to improve production efficiency.

The exemplary embodiments of the present disclosure can also be described as follows:

In one embodiment, an assembly substrate 10 includes an assembly base substrate 11 that serves as a structural support for subsequent conductive and insulating layers. A first assembly electrode AE1 is disposed on the assembly base substrate, and a second assembly electrode AE2 is also disposed on the assembly base substrate so as to face the first assembly electrode AE1 while being spaced apart from the first assembly electrode AE1 by an interval. The spacing between the first and second assembly electrodes defines a space SPC therebetween. A first coil electrode (19a in FIG. 2, or 29a in FIG. 5, or 39a in FIG. 6) is disposed on the assembly base substrate adjacent to the first and second assembly electrodes. The first coil electrode is arranged so as to enclose the space SPC in a plan view, thereby surrounding a region defined by the spacing between the first and second assembly electrodes. A first insulating layer (13a in FIG. 3 or 33a in FIG. 7) is disposed on the first coil electrode and electrically insulates the first coil electrode from upper conductive elements.

In another embodiment, the assembly substrate further includes a second coil electrode 19b disposed on the same plane as the first coil electrode 19a. The second coil electrode 19b extends outward from the first coil electrode 19a and encloses the first coil electrode 19a in a plan view so that the first and second coil electrodes are arranged concentrically or in a nested relationship. A portion of the first insulating layer is disposed between the first coil electrode and the second coil electrode, thereby maintaining electrical isolation between the two coplanar conductive patterns while preserving their relative planar alignment.

In a further embodiment, a third coil electrode 19c is disposed on the same plane as the second coil electrode 19b. The third coil electrode 19c extends outward from the second coil electrode 19b and encloses the second coil electrode 19b in a plan view, forming an additional concentric conductive pattern. A portion of the first insulating layer is disposed between the third coil electrode and the second coil electrode to provide insulation between the adjacent conductive rings or traces.

In some embodiments, the first coil electrode, second coil electrode, and third coil electrode are contiguously connected to one another, such that each successive electrode is an outward continuation of the previous one. More specifically, the second coil electrode extends continuously from one end of the first coil electrode, and the third coil electrode extends continuously from one end of the second coil electrode. Through this arrangement, the first, second, and third coil electrodes form a continuous conductive trace that spirals or meanders outward in a planar pattern.

In another embodiment, the assembly substrate further includes a first wiring line 14 and a second wiring line 15. The first wiring line 14 is connected to the third coil electrode 19c, and the second wiring line 15 is connected to the first coil electrode 19a. The first and second wiring lines are routed such that they extend in opposite directions from the space SPC defined between the first and second assembly electrodes. These wiring lines provide electrical connectivity for supplying or withdrawing current to and from the electrode pattern.

In another embodiment, the assembly substrate further includes a first assembly line connected to the first assembly electrode and a second assembly line connected to the second assembly electrode. At least one of the first assembly line and the second assembly line overlaps the first coil electrode in a plan view, indicating that a portion of the assembly line passes above or below the first coil electrode region when viewed from the top, without necessarily contacting the electrode directly. This overlap relationship allows compact routing of the assembly lines relative to the electrode pattern.

In another embodiment, a second coil electrode 29b is disposed concentrically with respect to the first coil electrode 29a, the second coil electrode 29b extending outward from the first coil electrode 29a and enclosing the first coil electrode 29a in a plan view. A third coil electrode 29c is disposed concentrically with respect to the second coil electrode 29b, extending outward from the second coil electrode 29b and enclosing the second coil electrode 29b in a plan view. The coil electrodes may thus be arranged as multiple concentric conductive rings or traces surrounding a common center corresponding to the space between the first and second assembly electrodes.

In yet another embodiment, the first, second, and third coil electrodes described above are contiguously connected such that the second coil electrode extends continuously from one end of the first coil electrode and the third coil electrode extends continuously from one end of the second coil electrode. The conductive pattern therefore forms a single, uninterrupted path across the three electrodes.

In a related embodiment, FIG. 5, the assembly substrate further includes a first wiring line 24 connected to the third electrode and a second wiring line 15 connected to the first coil electrode. The first wiring line and the second wiring line extend away from the space in the same direction, providing parallel routing of the electrical leads relative to the central region defined by the first and second assembly electrodes.

In another embodiment, a second insulating layer 33b is disposed on the first insulating layer 33a, and a second coil electrode 39b is disposed between the first insulating layer 33a and the second insulating layer 33b. The second coil electrode 39b is aligned with the first coil electrode 39a in a plan view so that their central axes or geometric centers coincide when viewed from above (see FIG. 7). This structure forms a vertically stacked pair of conductive layers separated by an insulating layer.

In a further embodiment, a first via FV extends through a portion of the first insulating layer to connect the first coil electrode 39a and the second coil electrode 39b. The via provides electrical continuity between the vertically spaced electrodes while maintaining the surrounding insulating integrity of the first insulating layer.

In yet another embodiment, a third insulating layer 33c is disposed on the second insulating layer 33b, and a third coil electrode 39c is disposed between the second insulating layer 33b and the third insulating layer 33c. The third coil electrode 39c is aligned with the first and second coil electrodes in a plan view so that all electrodes share a common alignment (see FIG. 7). A second via SV extends through a portion of the second insulating layer and connects the second coil electrode and the third coil electrode, thereby forming an electrically connected stack of three conductive layers separated by insulating layers.

In some embodiments, the first insulating layer, second insulating layer, and third insulating layer collectively define a through-opening 13H aligned with the space SPC defined by the first and second assembly electrodes. Portions of the first, second, and third insulating layers laterally surround edges of the first, second, and third coil electrodes, respectively, to provide lateral electrical insulation and mechanical support for the stacked electrode structure. The through-opening may serve as a cavity or recess corresponding to the area enclosed by the electrode patterns.

The exemplary embodiments of the present disclosure can further be described as follows:

According to an aspect of the present disclosure, there is provided an assembly substrate. The assembly substrate includes an assembly base substrate, a plurality of first assembly electrodes disposed on the assembly base substrate, a plurality of second assembly electrodes facing the plurality of first assembly electrodes with a predetermined interval on the assembly base substrate, an insulating layer disposed on the assembly base substrate and including a plurality of openings that overlaps the plurality of first assembly electrodes and the plurality of second assembly electrodes and a plurality of coils disposed on the plurality of first assembly electrodes and the plurality of second assembly electrodes and enclosing the plurality of openings.

The insulating layer may be disposed to enclose the plurality of coils.

The assembly substrate may further include a first wiring line connected to one end of the plurality of coils and a second wiring line connected to the other end of the plurality of coils. A voltage may be applied to the plurality of coils through the first wiring line and the second wiring line.

Each of the plurality of coils may include a plurality of coil electrodes spaced apart from the plurality of openings at different intervals.

Each of the plurality of coil electrodes may be disposed on the same layer.

The plurality of coil electrodes may include a first coil electrode enclosing the plurality of openings, a second coil electrode enclosing the first coil electrode, and a third coil electrode enclosing the second coil electrode.

A planar shape of each of the plurality of coil electrodes may be different from a planar shape of each of the plurality of openings.

A planar shape of each of the plurality of coil electrodes may correspond to a planar shape of each of the plurality of openings.

One coil of the plurality of coils may enclose one opening of the plurality of openings, and a center of each of the plurality of coil electrodes forming the one coil may coincide with a center of the one opening.

Each of the plurality of coils may include a plurality of coil electrodes spaced apart from the plurality of openings at the same interval.

Each of the plurality of coil electrodes may be disposed to overlap on different layers from one another.

The insulating layer may include a first insulating layer, a second insulating layer on the first insulating layer, and a third insulating layer on the second insulating layer. The plurality of coil electrodes may include a first coil electrode disposed below the first insulating layer, a second coil electrode disposed between the first insulating layer and the second insulating layer and connected to the first coil electrode through a contact hole of the first insulating layer and a third coil electrode disposed between the second insulating layer and the third insulating layer and connected to the second coil electrode through a contact hole of the second insulating layer.

One coil of the plurality of coils may enclose one opening of the plurality of openings, and a center of each of the plurality of coil electrodes forming the one coil may coincide with a center of the one opening.

One coil of the plurality of coils may enclose at least two openings of the plurality of openings.

The assembly substrate may further include a passivation layer disposed between the plurality of coils and the plurality of first assembly electrodes and the plurality of second assembly electrodes.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An assembly substrate, comprising:
an assembly base substrate;
a plurality of first assembly electrodes disposed on the assembly base substrate;
a plurality of second assembly electrodes disposed on the assembly base substrate, the plurality of second assembly electrodes facing the plurality of first assembly electrodes;
an insulating layer disposed on the assembly base substrate and including a plurality of openings that overlaps the plurality of first assembly electrodes and the plurality of second assembly electrodes; and
a plurality of coils disposed on the plurality of first assembly electrodes and the plurality of second assembly electrodes and enclosing the plurality of openings.

2. The assembly substrate according to claim 1, wherein the insulating layer is disposed to enclose the plurality of coils.

3. The assembly substrate according to claim 1, further comprising:
a first wiring line connected to one end of the plurality of coils; and
a second wiring line connected to the other end of the plurality of coils,
wherein, in operation, a voltage is applied to the plurality of coils through the first wiring line and the second wiring line.

4. The assembly substrate according to claim 1, wherein each of the plurality of coils includes a plurality of coil electrodes spaced apart from the plurality of openings at different intervals.

5. The assembly substrate according to claim 4, wherein each of the plurality of coil electrodes is disposed on the same layer.

6. The assembly substrate according to claim 5, wherein the plurality of coil electrodes includes a first coil electrode enclosing the plurality of openings, a second coil electrode enclosing the first coil electrode, and a third coil electrode enclosing the second coil electrode.

7. The assembly substrate according to claim 5, wherein a planar shape of each of the plurality of coil electrodes is different from a planar shape of each of the plurality of openings.

8. The assembly substrate according to claim 5, wherein a planar shape of each of the plurality of coil electrodes corresponds to a planar shape of each of the plurality of openings.

9. The assembly substrate according to claim 4, wherein one coil of the plurality of coils encloses one opening of the plurality of openings, and a center of each of the plurality of coil electrodes forming the one coil coincides with a center of the one opening.

10. The assembly substrate according to claim 1, wherein each of the plurality of coils includes a plurality of coil electrodes spaced apart from the plurality of openings at the same interval.

11. The assembly substrate according to claim 10, wherein each of the plurality of coil electrodes is disposed to overlap on different layers from one another.

12. The assembly substrate according to claim 10, wherein the insulating layer includes a first insulating layer, a second insulating layer on the first insulating layer, and a third insulating layer on the second insulating layer,
the plurality of coil electrodes includes:
a first coil electrode disposed below the first insulating layer;
a second coil electrode disposed between the first insulating layer and the second insulating layer and connected to the first coil electrode through a contact hole of the first insulating layer; and
a third coil electrode disposed between the second insulating layer and the third insulating layer and connected to the second coil electrode through a contact hole of the second insulating layer.

13. The assembly substrate according to claim 10, wherein one coil of the plurality of coils encloses one opening of the plurality of openings, and a center of each of the plurality of coil electrodes forming the one coil coincides with a center of the one opening.

14. The assembly substrate according to claim 1, wherein one coil of the plurality of coils encloses at least two openings of the plurality of openings.

15. The assembly substrate according to claim 1, further comprising:
a passivation layer disposed between the plurality of coils and the plurality of first assembly electrodes and the plurality of second assembly electrodes.

16. An assembly substrate, comprising:
an assembly base substrate;
a first assembly electrode disposed on the assembly base substrate;
a second assembly electrode disposed on the assembly base substrate, the second assembly electrode facing and spaced apart from the first assembly electrode to define a space therebetween;
a first electrode disposed on the assembly base substrate and adjacent to the first assembly electrode and the second assembly electrode, the first electrode enclosing the space in a plan view; and
a first insulating layer disposed on the first electrode.

17. The assembly substrate according to claim 16, further comprising:
a second electrode disposed on the same plane as the first electrode, the second electrode extending outward from the first electrode and enclosing the first electrode in a plan view,
wherein a portion of the first insulating layer is disposed between the first electrode and the second electrode.

18. The assembly substrate according to claim 17, further comprising:
a third electrode disposed on the same plane as the second electrode, the third electrode extending outward from the second electrode and enclosing the second electrode in a plan view,
wherein a portion of the first insulating layer is disposed between the third electrode and the second electrode.

19. The assembly substrate according to claim 18, wherein the first electrode, the second electrode, and the third electrode are contiguously connected to one another, such that the second electrode extends continuously from one end of the first electrode and the third electrode extends continuously from one end of the second electrode.

20. The assembly substrate according to claim 19, further comprising:
a first wiring line connected to the third electrode; and
a second wiring line connected to the first electrode,
wherein the first wiring line and the second wiring line extend in opposite directions from the space.

21. The assembly substrate according to claim 16, further comprising:
a first assembly line connected to the first assembly electrode; and
a second assembly line connected to the second assembly electrode,
wherein at least one of the first assembly line and the second assembly line overlaps the first electrode in a plan view.

22. The assembly substrate according to claim 16, further comprising:
a second electrode disposed concentrically with respect to the first electrode, the second electrode extending outward from the first electrode and enclosing the first electrode in a plan view;
a third electrode disposed concentrically with respect to the second electrode, the third electrode extending outward from the second electrode and enclosing the second electrode in a plan view.

23. The assembly substrate according to claim 22, wherein the first electrode, the second electrode, and the third electrode are contiguously connected to one another, such that the second electrode extends continuously from one end of the first electrode and the third electrode extends continuously from one end of the second electrode.

24. The assembly substrate according to claim 22, further comprising:
a first wiring line connected to the third electrode; and
a second wiring line connected to the first electrode,
wherein the first wiring line and the second wiring line extend away from the space in the same direction.

25. The assembly substrate according to claim 16, further comprising:
a second insulating layer disposed on the first insulating layer; and
a second electrode disposed between the first insulating layer and the second insulating layer, the second electrode being aligned with the first electrode in a plan view.

26. The assembly substrate according to claim 25, further comprising a first via extending through a portion of the first insulating layer and connecting the first electrode and the second electrode.

27. The assembly substrate according to claim 26, further comprising:
a third insulating layer disposed on the second insulating layer;
a third electrode disposed between the second insulating layer and the third insulating layer, the third electrode being aligned with the first electrode and the second electrode in a plan view; and
a second via extending through a portion of the second insulating layer and connecting the second electrode and the third electrode.

28. The assembly substrate according to claim 27, wherein the first insulating layer, the second insulating layer, and the third insulating layer define a through-opening aligned with the space, and portions of the first insulating layer, the second insulating layer, and the third insulating layer laterally surround edges of the first electrode, the second electrode, and the third electrode, respectively.
